(19) United States
(12) Patent Application Publication
(10) Pub. No.: US 2024/0431186 A1
(43) Pub. Date: Dec. 26, 2024

(54) BLACK PHOTOSENSITIVE RESIN COMPOSITION, BLACK PARTITION WALL USING THE SAME, DISPLAY DEVICE, AND MANUFACTURING METHOD OF PARTITION WALL

(71) Applicant: Samsung SDI Co., Ltd., Yongin-si (KR)

(72) Inventors: JUHO JUNG, Suwon-si (KR); Baek Soung Park, Suwon-si (KR); Seungbeom Kee, Suwon-si (KR); Jieun Kim, Suwon-si (KR); Jihong Kim, Suwon-si (KR); Donghyun Park, Suwon-si (KR)

(21) Appl. No.: 18/752,980

(22) Filed: Jun. 25, 2024

(30) Foreign Application Priority Data
Jun. 26, 2023 (KR) 10-2023-0082163
May 27, 2024 (KR) 10-2024-0068608

(51) Int. Cl. H10K 59/80; G03F 7/00; G03F 7/033; H10K 59/38

(52) U.S. Cl. CPC H10K 59/8792; G03F 7/0007; G03F 7/033; H10K 59/38; H10K 59/879

(57) ABSTRACT

A black photosensitive resin composition, a black partition wall manufactured using the same, a display device including the black partition wall, and a method of manufacturing the black partition wall, the black photosensitive resin composition includes a binder resin; a black colorant including lactam black; a photopolymerizable monomer, a photopolymerization initiator; and a solvent, wherein the black photosensitive resin composition has an optical density (OD) per 1 μm of greater than or equal to about 1.5.

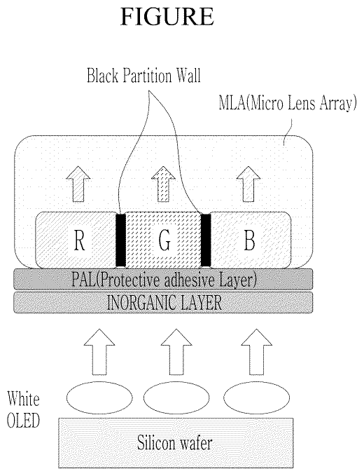

### CROSS-REFERENCE TO RELATED APPLICATION

This application claims priority to and the benefit of Korean Patent Application No. 10-2023-0082163 filed in the Korean Intellectual Property Office on Jun. 26, 2023, and Korean Patent Application No. 10-2024-0068608 filed in the Korean Intellectual Property Office on May 27, 2024, the entire contents of which are incorporated herein by reference.

### BACKGROUND

### 1 Field

Embodiments relate to a black photosensitive resin composition, a black partition wall using the same, a display device, and a method of manufacturing the black partition wall.

### 2. Description of the Related Art

Recently, interest in self-emitting (emissive) micro OLED display panels, which may be applied to VR (Virtual Reality), AR (Augmented Reality), and MR (Mixed Reality) devices, are increasing.

### SUMMARY

The embodiments may be realized by providing a black photosensitive resin composition including a binder resin; a black colorant including lactam black; a photopolymerizable monomer; a photopolymerization initiator; and a solvent, wherein the black photosensitive resin composition has an optical density (OD) per 1 μm of greater than or equal to about 1.5.

The black colorant may be included in an amount of about 60 wt % to about 80 wt %, based on a total weight of the black photosensitive resin composition.

The black colorant may include a lactam black mill base.

The black photosensitive resin composition may have an OD per 1 μm of greater than or equal to about 2.0.

The black photosensitive resin composition may be curable at a temperature of less than or equal to about 100° C.

The binder resin may include an acrylic binder resin.

The acrylic binder resin may have a double bond equivalent weight of greater than or equal to about 340 g/mol.

The black photosensitive resin composition may include, based on a total weight of the black photosensitive resin composition about 1 wt % to about 10 wt % of the binder resin; about 60 wt % to about 80 wt % of the black colorant; about 0.5 wt % to about 5 wt % of the photopolymerizable monomer; about 0.1 wt % to about 3 wt % of the photopolymerization initiator; and the solvent.

The black photosensitive resin composition may further include malonic acid, 3-amino-1,2-propanediol, a silane coupling agent, a leveling agent, a surfactant, a polymerization inhibitor, or a combination thereof.

The embodiments may be realized by providing a black partition wall manufactured using the black photosensitive resin composition according to an embodiment.

The embodiments may be realized by providing a display device comprising the black partition wall according to an embodiment.

The display device may be a micro OLED display device including an OLED substrate deposited on a silicon wafer, an inorganic layer stacked on the OLED substrate, an adhesive protection layer stacked on the inorganic layer and a color filter layer that is stacked on the adhesive protection layer and converts white light generated from the OLED substrate into a plurality of color lights, the color filter layer may include a red color filter, a green color filter, and a blue color filter, and the black partition wall may be between each color filter of the color filter layer.

The display device may further include a micro lens array on the adhesive protection layer and surrounding the color filter layer and the black partition wall.

The adhesive protection layer may have a thickness of less than or equal to about 1 μm.

The color filter layer may have a thickness of about 1.1 μm to about 1.6 μm.

The black partition wall may have a thickness of about 0.5 μm to about 1.2 μm.

The inorganic layer may have a thickness of less than or equal to about 2 μm.

The embodiments may be realized by providing a method of manufacturing a black partition wall including coating the black photosensitive resin composition according to an embodiment; prebaking at a temperature of less than or equal to about 100° C. after the coating; exposing to i-line after the prebaking, and developing after the exposing.

### BRIEF DESCRIPTION OF THE DRAWING

Features will be apparent to those of skill in the art by describing in detail exemplary embodiments with reference to the attached drawing in which:

the FIGURE IS a schematic view showing the structure of a micro OLED display device according to some embodiments.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing FIGURE, the dimensions of layers and regions may be exaggerated for clarity of illustration. It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present. As used herein, the term “or” is not necessarily an exclusive term, e.g., “A or B” would include A, B, or A and B. As used herein, hydrogen substitution (—H) may include deuterium substitution (-D) or tritium substitution (-T). For example, any hydrogen in any compound described herein may be protium, deuterium, or tritium (e.g., based on natural or artificial substitution).

As used herein, when specific definition is not otherwise provided, “alkyl group” refers to a C1 to C20 alkyl group, “alkenyl group” refers to a C2 to C20 alkenyl group, “cycloalkenyl group” refers to a C3 to C20 cycloalkenyl group, “heterocycloalkenyl group” refers to a C3 to C20 heterocycloalkenyl group, “aryl group” refers to a C6 to C20 aryl group, “arylalkyl group” refers to a C6 to C20 arylalkyl group, “alkylene group” refers to a C1 to C20 alkylene group, “arylene group” refers to a C6 to C20 arylene group, “alkylarylene group” refers to a C6 to C20 alkylarylene group, “heteroarylene group” refers to a C3 to C20 heteroarylene group, and “alkoxylene group” refers to a C1 to C20 alkoxylene group.

As used herein, when specific definition is not otherwise provided, “substituted” refers to replacement of at least one hydrogen of a compound by a substituent selected from a halogen atom (F, Cl, Br, or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

As used herein, when specific definition is not otherwise provided, “hetero” refers to inclusion of at least one heteroatom of N, O, S, and P, in the chemical formula.

As used herein, when specific definition is not otherwise provided, “(meth)acrylate” refers to both “acrylate” and “methacrylate,” and “(meth)acrylic acid” refers to “acrylic acid” and “methacrylic acid”.

As used herein, when a definition is not otherwise provided, the term “combination” refers to mixing or copolymerization. Additionally, “copolymerization” refers to block copolymerization to random copolymerization, and “copolymer” refers to block copolymerization to random copolymerization.

In the chemical formula of the present specification, unless a specific definition is otherwise provided, hydrogen is bonded at the position when a chemical bond is not drawn where supposed to be given.

As used herein, when a definition is not otherwise provided, “*” refers to a linking part between the same or different atoms, or chemical formulas.

A black photosensitive resin composition according to some embodiments may include, e.g., (A) a binder resin; (B) a black colorant including lactam black; (C) a photopolymerizable monomer; (D) a photopolymerization initiator; and (E) a solvent. In an implementation, the black photosensitive resin composition may have an optical density (OD) per 1 μm of greater than or equal to about 1.5.

Some color photoresists may be a negative photosensitive liquid material implemented in color patterns of red, green, and blue, and technology development has been made in the direction of gradually modifying the composition of the liquid material.

Efforts have been made to improve color purity by modifying the type or content of the pigment dispersion, which is a coloring material that implements the color pattern, to improve patternability by modifying the composition of the binder resin or photopolymerization initiator, or to improve coating properties and color uniformity through the use of other additives such as leveling agents.

The photosensitive resin composition according to an embodiment, which is a black photosensitive resin composition capable of forming a black partition wall between red, green, and blue color filters, may enable high color reproducibility, realize high-resolution pixels, prevent the light leakage phenomenon, and form ultra-high-resolution patterns to be optimal for displays for VR (Virtual Reality), AR (Augmented Reality), and MR (Mixed Reality), which are next generation displays, and may help secure high reliability and patternability with a low temperature and photocuring alone, which is very advantageous in terms of process.

Hereinafter, each component is described in detail.

### (A) Binder Resin

The binder resin may include, e.g., an acrylic binder resin.

The acrylic binder resin may be, e.g., a copolymer of a first ethylenic unsaturated monomer and a second ethylenic unsaturated monomer that is copolymerizable therewith, and may be a resin including at least one acrylic repeating unit.

The first ethylenic unsaturated monomer may be an ethylenic unsaturated monomer including at least one carboxyl group. Examples of the monomer may include acrylic acid, methacrylic acid, maleic acid, itaconic acid, fumaric acid, or a combination thereof.

The first ethylenic unsaturated monomer may be included in an amount of about 5 wt % to about 50 wt %, e.g., about 10 wt % to about 40 wt %, based on a total weight of the acrylic binder resin.

Examples of the second ethylenic unsaturated monomer may include an aromatic vinyl compound such as styrene, α-methylstyrene, vinyltoluene, vinylbenzylmethylether, and the like; an unsaturated carboxylic acid ester compound such as methyl(meth)acrylate, ethyl(meth)acrylate, butyl(meth)acrylate, 2-hydroxyethyl(meth)acrylate, 2-hydroxy butyl(meth)acrylate, benzyl (meth)acrylate, cyclohexyl(meth)acrylate, phenyl(meth)acrylate, and the like; an unsaturated carboxylic acid amino alkyl ester compound such as 2-aminoethyl(meth)acrylate, 2-dimethylaminoethyl(meth)acrylate, and the like; a carboxylic acid vinyl ester compound such as vinyl acetate, vinyl benzoate, and the like; an unsaturated carboxylic acid glycidyl ester compound such as glycidyl (meth)acrylate and the like; a vinyl cyanide compound such as (meth)acrylonitrile and the like; an unsaturated amide compound such as (meth)acrylamide and the like; and the like, and may be used alone or as a mixture of two or more.

Examples of the acrylic binder resin may include a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, a (meth)acrylic acid/benzylmethacrylate/styrene/2-hydroxyethylmethacrylate copolymer and the like, and may be used alone or as a mixture of two or more.

The acrylic binder resin may have a weight average molecular weight of about 3,000 g/mol to about 20,000 g/mol and a double bond equivalent weight of greater than or equal to about 340 g/mol. Maintaining the weight average molecular weight and the double bond equivalent weight of the acrylic binder resin within the above ranges, excellent pattern formation properties may be achieved, and the produced thin film may have excellent mechanical and thermal characteristics.

The binder resin may further include an epoxy binder resin.

The binder resin may help improve heat resistance by further including an epoxy binder resin. The epoxy binder resin may include, e.g., a phenol novolac epoxy resin, a tetramethyl biphenyl epoxy resin, a bisphenol A-type epoxy resin, a bisphenol F-type epoxy resin, an alicyclic epoxy resin, or a combination thereof.

In an implementation, the binder resin including the epoxy binder resin may help ensure the dispersion stability of colorants such as pigments, which will be described below, and may help form pixels with a desired resolution during the development process.

The epoxy binder resin may be included in an amount of about 1 wt % to about 10 wt %, e.g., about 5 wt % to about 10 wt %, based on a total weight of the binder resin. Maintaining the amount of the epoxy binder resin within the above ranges may help ensure that the remaining film rate and chemical resistance may be greatly improved.

The epoxy binder resin may have an epoxy equivalent weight of about 150 g/eq to about 200 g/eq. Maintaining the epoxy equivalent weight of the epoxy binder resin within the above range may help ensure that there is a beneficial effect in improving the curability of the formed pattern and fixing the colorant in the structure in which the pattern is formed.

The binder resin may be dissolved in a solvent described below in solid form to form a photosensitive resin composition. In this case, the binder resin in the solid form may be included in an amount of about 0.1 wt % to about 30 wt %, e.g., about 20 wt % to about 30 wt %, based on a total weight of the binder resin solution dissolved in the solvent.

In an implementation, the binder resin may be included in an amount of about 0.1 wt % to about 20 wt %, e.g., about 0.5 wt % to about 15 wt %, or about 1 wt % to about 10 wt %, based on a total weight of the photosensitive resin composition. By including the binder resin within the above ranges, excellent sensitivity, developability, resolution, and linearity of the pattern may be obtained.

### (B) Black Colorant

A black colorant included in the photosensitive resin composition according to an embodiment may include, e.g., lactam black to help increase light-blocking properties and thus easily realize black.

In order to improve the light-blocking properties, carbon black alone could be used as the black colorant, and excellent optical density could be obtained, but other characteristics excluding optical density such as electric characteristics and the like could be deteriorated. In particular, if the carbon black alone were to be used, low-temperature curing and high-resolution pattern formation could be impossible due to reduced transmittance in a UV region, resulting in being not applied to micro OLED displays, which are next generation displays applied to VR (Virtual Reality), AR (Augmented Reality), and MR (Mixed Reality) devices.

Accordingly, an organic black pigment (e.g., color mixing, etc. such as RGB black and the like) may be used as the black colorant, as opposed to using the carbon black alone, which may relatively only slightly deteriorate light-blocking properties but may still have sufficient light-blocking performance and simultaneously, may help improve other characteristics such as electric characteristics and the like. However, this could result in very low optical density and even if better than the case of using the carbon black alone, still low transmittance in a UV region, forming inferior patterns, and thus may also have issues in being applied to the micro OLED displays, which are next generation displays.

And, this could also occur if further including the carbon black with the organic black pigment as the black colorant in the photosensitive resin composition.

Accordingly, lactam black may be used instead of the other black colorant (such as the carbon black or the organic black pigment). In an implementation, in the black photosensitive resin composition according to an embodiment, the lactam black-containing black colorant may be included in an amount of about 60 wt % to about 80 wt %, e.g., about 60 wt % to about 70 wt %, based on a total weight of the black photosensitive resin composition. In an implementation, the optical density (OD) may be much easily controlled to be greater than or equal to about 1.5 per 1 μm, e.g., greater than or equal to about 2.0 per 1 μm, and furthermore, the transmittance decrease in a UV region may be prevented, and in addition, the low temperature curing and high-resolution pattern formation of about 2 μm or less may be facilitated, and the black photosensitive resin composition according to an embodiment may be applied without difficulties to the micro OLED displays, which are next generation displays.

In an implementation, the black colorant may be composed of or include, e.g., a lactam black mill base.

The lactam black mill base may include, e.g., solid lactam black, a dispersant, and a solvent described below. In an implementation, the lactam black may be used by previously surface-treating it with a dispersant, or the dispersant may be added together with the lactam black when preparing the composition. A solid content of lactam black may be about 5 wt % to about 40 wt %, e.g., about 8 wt % to about 30 wt %, based on a total weight of the lactam black mill base.

The dispersant may be a non-ionic dispersant, an anionic dispersant, a cationic dispersant, or the like. Examples of the dispersant may include polyalkylene glycol and esters thereof, polyoxy alkylene, polyhydric alcohol ester alkylene oxide addition product, alcohol alkylene oxide addition product, sulfonate ester, a sulfonate salt, carboxylate ester, a carboxylate salt, alkyl amide alkylene oxide addition product, alkyl amine, and the like, and may be used alone or as a mixture of two or more.

Commercially available examples of the dispersant may include DISPERBYK-101, DISPERBYK-130, DISPERBYK-140, DISPERBYK-160, DISPERBYK-161, DISPERBYK-162, DISPERBYK-163, DISPERBYK-164, DISPERBYK-165, DISPERBYK-166, DISPERBYK-170, DISPERBYK-171, DISPERBYK-182, DISPERBYK-2000, DISPERBYK-2001, and the like made by BYK Co., Ltd.; EFKA-47, EFKA-47EA, EFKA-48, EFKA-49, EFKA-100, EFKA-400, EFKA-450, and the like made by EFKA Chemicals Co.; Solsperse 5000, Solsperse 12000, Solsperse 13240, Solsperse 13940, Solsperse 17000, Solsperse 20000, Solsperse 24000GR, Solsperse 27000, Solsperse 28000, and the like made by Zeneka Co.; or PB711, or PB821 made by Ajinomoto Inc.

The dispersant may be included in an amount of about 0.1 wt % to about 15 wt %, based on a total weight of the black photosensitive resin composition. By including the dispersant within the above range, the dispersibility of the composition may be excellent, and thus stability, developability, and patternability may be excellent during manufacturing of a black partition wall.

The lactam black may also be used after pre-treatment using a water-soluble inorganic salt and a wetting agent, and an average particle size of the lactam black may be fine.

The pre-treatment may be performed by kneading the lactam black with a water-soluble inorganic salt and a wetting agent and then, filtering and washing the kneaded lactam black.

The kneading may be performed at a temperature of about 40° C. to about 100° C., and the filtering and washing may be performed by filtering the pigment after washing away an inorganic salt with water and the like.

Examples of the water-soluble inorganic salt may include sodium chloride, potassium chloride, and the like. The wetting agent may make the pigment to be uniformly mixed with the water-soluble inorganic salt uniformly and be pulverized. Examples of the wetting agent may include alkylene glycol monoalkyl ethers such as ethylene glycol monoethylether, propylene glycol monomethylether, diethylene glycol monomethylether, and the like, and alcohols such as ethanol, isopropanol, butanol, hexanol, cyclohexanol, ethylene glycol, diethylene glycol, polyethylene glycol, glycerine polyethylene glycol, and the like. These may be used alone or as a mixture of two or more.

The lactam black (after the kneading) may have an average particle diameter of about 5 nm to about 200 nm, e.g., about 5 nm to about 150 nm. Maintaining the average particle diameter of the lactam black within the above ranges may help ensure that stability in the lactam black mill base may be improved, and there may be little or no concern about deterioration of pixel resolution.

In addition to the lactam black, the black colorant may further include an organic black pigment such as color mixing such as the aforementioned carbon black or RGB black.

### (C) Photopolymerizable Monomer

The photopolymerizable monomer in the black photosensitive resin composition according to some embodiments may be a single compound or a mixture of two (or more) different compounds.

In an implementation, the photopolymerizable monomer may be a mixture of two different compounds, and one of the two compounds may be a compound including at least two functional groups represented by Chemical Formula 1.

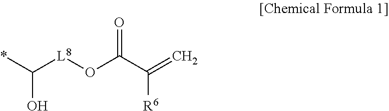

In Chemical Formula 1, R⁶ may be, e.g., a hydrogen atom or a substituted or unsubstituted C1 to C10 alkyl group.

L⁸ may be, e.g., a single bond or a substituted or unsubstituted C1 to C10 alkylene group.

In an implementation, the compound including at least two functional groups represented by Chemical Formula 1 may include 2 to 6 functional groups represented by Chemical Formula 1, and sufficient polymerization may occur during exposure in the pattern formation process to form a pattern with excellent heat resistance, light resistance, and chemical resistance.

In an implementation, the compound including at least two functional groups represented by Chemical Formula 1 may be a compound represented by Chemical Formula 2 or Chemical Formula 3.

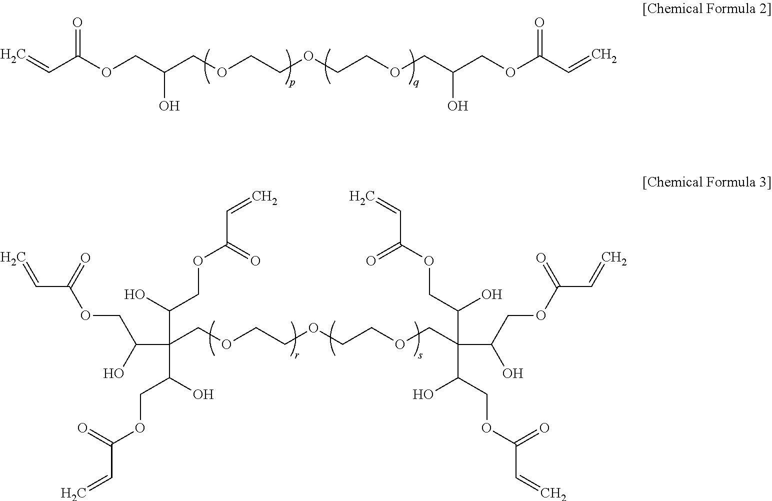

In Chemical Formula 2 and Chemical Formula 3, p, q, r, and s may each independently be, e.g., an integer of 1 to 10.

In an implementation, the photopolymerizable monomer may be a mixture of two different compounds, and the other one of the two compounds may be a monofunctional or multifunctional ester compound of (meth)acrylic acid having at least one ethylenically unsaturated double bond.

The monofunctional or multifunctional ester compound of (meth)acrylic acid having at least one ethylenically unsaturated double bond may include, e.g., ethylene glycoldi(meth)acrylate, diethylene glycoldi(meth)acrylate, triethylene glycoldi(meth)acrylate, propylene glycoldi(meth)acrylate, neopentylglycoldi(meth)acrylate, 1,4-butanedioldi(meth)acrylate, 1,6-hexanedioldi(meth)acrylate, bisphenol A di(meth)acrylate, pentaerythritoldi(meth)acrylate, pentaerythritoltri(meth)acrylate, pentaerythritoltetra(meth)acrylate, pentaerythritolhexa(meth)acrylate, dipentaerythritoldi(meth)acrylate, dipentaerythritoltri(meth)acrylate, dipentaerythritolpenta(meth)acrylate, dipentaerythritolhexa(meth)acrylate, bisphenol A epoxy (meth)acrylate, ethylene glycolmonomethylether (meth)acrylate, trimethylolpropanetri(meth)acrylate, tris(meth)acryloyloxyethylphosphate, novolac epoxy (meth)acrylate, or a combination thereof.

Commercially available products of the monofunctional or multifunctional ester compound of (meth)acrylic acid having at least one ethylenically unsaturated double bond may be as follows. Examples of the mono-functional ester of (meth)acrylic acid may include Aronix M-101®, M-111®, M-114® (Toagosei Chemistry Industry Co., Ltd.); KAYARAD TC-110S®, TC-120SR (Nippon Kayaku Co., Ltd.); V-158®, V-2311® (Osaka Organic Chemical Ind., Ltd.), and the like. Examples of a di-functional ester of (meth)acrylic acid may include Aronix M-210®, M-240®, M-6200® (Toagosei Chemistry Industry Co., Ltd.), KAYARAD HDDAR, HX-220R, R-604® (Nippon Kayaku Co., Ltd.), V-260x, V-312°, V-335 HP® (Osaka Organic Chemical Ind., Ltd.), and the like. Examples of a tri-functional ester of (meth)acrylic acid may include Aronix M-309®, M-400®, M-405®, M-450x, M-7100®, M-8030®, M-8060® (Toagosei Chemistry Industry Co., Ltd.), KAYARAD TMPTAR, DPCA-20®, DPCA-30x, DPCA-60€, DPCA-120® (Nippon Kayaku Co., Ltd.), V-295° C., V-300®, V-360™, V-GPTR, V-3PAR, V-400® (Osaka Yuki Kayaku Kogyo Co. Ltd.), and the like. These may be used alone or as a mixture of two or more.

The photopolymerizable monomer may be used after being treated with an acid anhydride to provide better developability.

The photopolymerizable monomer may be included in an amount of about 0.5 wt % to about 10 wt %, e.g., about 0.5 wt % to about 5 wt % or about 1 wt % to about 5 wt %, based on a total weight of the black photosensitive resin composition. By including the photopolymerizable monomer within the above ranges, curing may occur sufficiently during exposure to light in a pattern formation process, resulting in excellent reliability, excellent heat resistance, light resistance, and chemical resistance of the pattern, and excellent resolution and adhesion.

### (D) Photopolymerization Initiator

The black photosensitive resin composition according to some embodiments may include a photopolymerization initiator. The photopolymerization initiator may include an acetophenone compound, a benzophenone compound, a thioxanthone compound, a benzoin compound, a triazine compound, an oxime compound, or the like.

Examples of the acetophenone compound may include 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloroacetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

Examples of the benzophenone compound may include benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone,4,4′-dichlorobenzophenone, 3,3′-dimethyl-2-methoxybenzophenone, and the like.

Examples of the thioxanthone compound may include thioxanthone, 2-chlorothioxanthone, 2-methylthioxanthone, isopropyl thioxanthone, 2,4-diethyl thioxanthone, 2,4-diisopropyl thioxanthone, and the like.

Examples of the benzoin compound may include benzoin, benzoin methyl ether, benzoin ethyl ether, benzoin isopropyl ether, benzoin isobutyl ether, benzyl dimethyl ketal, and the like.

Examples of the triazine compound may include 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl 4,6-bis(trichloro methyl)-s-triazine, bis(trichloromethyl)-6-styryl-s-triazine, 2-(naphthol-yl)-4,6-bis(trichloromethyl)-s-triazine, 2-(4-methoxynaphthol-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

Examples of the oxime compound may include an O-acyloxime compound, 2-(O-benzoyloxime)-1-[4-(phenylthio)phenyl]-1,2-octanedione, 1-(O-acetyloxime)-1-[9-ethyl-6-(2-methylbenzoyl)-9H-carbazol-3-yl]ethanone, O-ethoxycarbonyl-α-oxyamino-1-phenylpropan-1-one, and the like. Examples of the O-acyloxime compound may include 1,2-octanedione, 2-dimethylamino-2-(4-methylbenzyl)-1-(4-morpholin-4-yl-phenyl)-butan-1-one, 1-(4-phenylsulfanyl phenyl)-butane-1,2-dione-2-oxime-O-benzoate, 1-(4-phenylsulfanyl phenyl)-octane-1,2-dione-2-oxime-O-benzoate, 1-(4-phenylsulfanyl phenyl)-octan-1-oneoxime-O-acetate, 1-(4-phenylsulfanyl phenyl)-butan-1-oneoxime-O-acetate, and the like.

In addition to the above compounds, the photopolymerization initiator may also be used together with, e.g., a carbazole compound, a diketone compound, a sulfonium borate compound, a diazo compound, an imidazole compound, a biimidazole compound, or the like.

The photopolymerization initiator may be included in an amount of about 0.1 wt % to about 5 wt %, e.g., about 0.1 wt % to about 3 wt %, based on a total weight of the black photosensitive resin composition. By including the photopolymerization initiator within the above ranges, sufficient photopolymerization may occur during exposure in the pattern formation process for manufacturing the color filter, resulting in excellent sensitivity and improved transmittance.

### (E) Solvent

The solvent may be a material that has compatibility with the pigment dispersion including the black colorant, the binder resin, the photopolymerizable monomer, and the photopolymerization initiator but does not react therewith.

Examples of the solvent may include alcohols such as methanol, ethanol, and the like; ethers such as dichloroethylether, n-butylether, diisoamylether, methylphenylether, tetrahydrofuran, and the like; glycolethers such as ethylene glycolmonomethylether, ethylene glycolmonoethylether, ethylene glycoldimethylether, and the like; cellosolveacetates such as methylcellosolveacetate, ethylcellosolveacetate, diethylcellosolveacetate, and the like; carbitols such as methylethylcarbitol, diethylcarbitol, diethylene glycolmonomethylether, diethylene glycolmonoethylether, diethylene glycoldimethylether, diethylene glycolethylmethylether, diethylene glycoldiethylether, and the like; propylene glycolalkyletheracetates such as propylene glycolmethyletheracetate, propylene glycolpropyletheracetate, and the like; aromatic hydrocarbons such as toluene, xylene, and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; lactate esters such as methyl lactate, ethyl lactate, and the like; oxy acetic acid alkyl esters such as oxy methyl acetate, oxy ethyl acetate, oxy butyl acetate, and the like; alkoxy acetic acid alkyl esters such as methoxy methyl acetate, methoxy ethyl acetate, methoxy butyl acetate, ethoxy methyl acetate, ethoxy ethyl acetate, and the like; 3-oxypropionic acid alkyl esters such as 3-oxymethyl propionate, 3-oxyethyl propionate, and the like; 3-alkoxypropionic acid alkyl esters such as 3-methoxymethyl propionate, 3-methoxyethyl propionate, 3-ethoxyethyl propionate, 3-ethoxymethyl propionate, and the like; 2-oxypropionic acid alkyl esters such as 2-oxymethyl propionate, 2-oxyethyl propionate, 2-oxypropyl propionate, and the like; 2-alkoxypropionic acid alkyl esters such as 2-methoxymethyl propionate, 2-methoxyethyl propionate, 2-ethoxyethyl propionate, 2-ethoxymethyl propionate, and the like; 2-oxy-2-methylpropionic acid esters such as 2-oxy-2-methylmethyl propionate, 2-oxy-2-methylethyl propionate, and the like, monooxy monocarboxylic acid alkyl esters of 2-alkoxy-2-methyl alkyl propionates such as 2-methoxy-2-methylmethyl propionate, 2-ethoxy-2-methylethyl propionate, and the like; esters such as 2-hydroxyethyl propionate, 2-hydroxy-2-methylethyl propionate, hydroxy ethyl acetate, 2-hydroxy-3-methyl methyl butanoate, and the like; ketonate esters such as ethyl pyruvate, and the like. In an implementation, a high boiling point solvent such as N-methylformamide, N,N-dimethyl formamide, N-methylformanilide, N-methylacetamide, N,N-dimethyl acetamide, N-methylpyrrolidone, dimethylsulfoxide, benzylethylether, dihexylether, acetylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, phenyl cellosolve acetate, or the like, may be also used.

Considering miscibility and reactivity, glycolethers such as ethylene glycolmonoethylether, ethylene glycoldimethylether, ethylene glycoldiethylether, diethylene glycolethylmethylether, and the like; ethylene glycolalkylether acetates such as ethyl cellosolveacetate, and the like; esters such as 2-hydroxyethyl propionate, and the like; carbitols such as diethylene glycolmonomethylether, and the like; propylene glycolalkyletheracetates such as propylene glycolmonomethyl ether acetate, propylene glycolpropyletheracetate, or the like may be used.

The solvent may be included in a balance amount, e.g., about 10 wt % to about 40 wt % or about 10 wt % to about 30 wt %, based on a total weight of the black photosensitive resin composition. By including the solvent within these ranges, the black photosensitive resin composition may have an appropriate viscosity and thus processability is improved during a production of a black partition wall.

### (F) Other Additives

In an implementation, the black photosensitive resin composition may further include an additive, e.g., malonic acid, 3-amino-1,2-propanediol, a silane coupling agent, a leveling agent, a surfactant, a polymerization inhibitor, or a combination thereof.

The silane coupling agent may have a reactive substituent such as a vinyl group, a carboxyl group, a methacryloxy group, an isocyanate group, or an epoxy group to improve adhesion to the substrate.

Examples of the silane coupling agent may include trimethoxysilylbenzoic acid, γ-methacryloxypropyltrimethoxysilane, vinyltriacetoxysilane, vinyltrimethoxysilane, Y-isocyanatepropyltriethoxysilane, γ-glycidoxypropyltrimethoxysilane, β-(3,4-epoxycyclohexyl)ethyltrimethoxysilane, and the like. These may be used alone or in a mixture of two or more.

The silane coupling agent may be included in an amount of about 0.01 parts by weight to about 10 parts by weight, based on 100 parts by weight of the photosensitive resin composition. By including the silane coupling agent within the above range, adhesion, storage capability, and the like may be improved.

In an implementation, the photosensitive resin composition may further include a surfactant, e.g., a fluorine surfactant or a silicone surfactant, to help improve coating properties and prevent defect formation.

Examples of the fluorine surfactant may include a commercial fluorine surfactant such as BM-1000®, BM-1100®, and the like of BM Chemie Inc.; MEGAFACE F 142D®, MEGAFACE F 172®, MEGAFACE F 173®, MEGAFACE F 183®, MEGAFACE F 554®, and the like of Dainippon Ink Kagaku Kogyo Co., Ltd.; FULORAD FC-135®, FULORAD FC-170C®, FULORAD FC-430®, FULORAD FC-431®, and the like of SUMITOMO 3M Co., Ltd.; SURFLON S-112®, SURFLON S-113®, SURFLON S-131®, SURFLON S-141®, SURFLON S-145x, and the like of Asahi Glass Co., Ltd.; SH-28PAR, SH-190®, SH-193®, SZ-6032R, SF-8428° C., and the like of: Toray Silicone Co., Ltd.

The silicone surfactant may be a commercial silicone surfactant such as BYK-307, BYK-333, BYK-361N, BYK-051, BYK-052, BYK-053, BYK-067A, BYK-077, BYK-301, BYK-322, BYK-325, and the like of BYK Chem.

The surfactant may be included in an amount of about 0.001 parts by weight to about 5 parts by weight, based on 100 parts by weight of the photosensitive resin composition. By including the surfactant within the range, coating uniformity may be secured, a stain may not be produced, and wetting on an IZO substrate or a glass substrate is improved.

The polymerization inhibitor may include a hydroquinone compound, a catechol compound, or a combination thereof. In an implementation, the black photosensitive resin composition according to some embodiments may further include the hydroquinone compound, the catechol compound, or a combination thereof, and room temperature crosslinking may be prevented during exposure to light after coating the black photosensitive resin composition.

In an implementation, the hydroquinone compound, catechol compound, or combination thereof may include hydroquinone, methyl hydroquinone, methoxyhydroquinone, t-butyl hydroquinone, 2,5-di-t-butyl hydroquinone, 2,5-bis(1,1-dimethylbutyl) hydroquinone, 2,5-bis(1,1,3,3-tetramethylbutyl) hydroquinone, catechol, t-butyl catechol, 4-methoxyphenol, pyrogallol, 2,6-di-t-butyl-4-methylphenol, 2-naphthol, tris(N-hydroxy-N-nitrosophenylaminato-O,O′)aluminum, or a combination thereof.

The hydroquinone compound, catechol compound, or combination thereof may be used in the form of a dispersion, and the polymerization inhibitor in the form of the dispersion may be included in an amount of about 0.001 wt % to about 3 wt %, e.g., about 0.01 wt % to about 1 wt %, based on a total weight of the black photosensitive resin composition. By including the polymerization inhibitor within the above ranges, it is possible to address the issue of aging at room temperature and to help prevent deterioration of sensitivity and surface peeling.

In an implementation, the black photosensitive resin composition may include other additives, e.g., an antioxidant, a stabilizer, or the like, in a suitable amount, unless they deteriorate properties of the black photosensitive resin composition.

The black photosensitive resin composition according to some embodiments may be either positive or negative. In an implementation, the composition may be negative to completely remove residues in regions where a pattern is exposed after exposing and developing the composition having light blocking properties.

Another embodiment provides a black partition wall manufactured by exposing, developing, and curing the aforementioned photosensitive resin composition.

A method of manufacturing the black partition wall is as follows.

### (1) Coating and Film Formation

The black photosensitive resin composition may be coated to have a desired thickness on a substrate such as a glass substrate or ITO substrate, or the like which undergoes a predetermined pre-treatment, using a spin or slit coating method, a roll coating method, a screen-printing method, an applicator method, or the like, and may be heated at about 100° C. for about 1 minute to 10 minutes to remove a solvent and thereby to form a photosensitive resin layer. Through this step, it may be possible to improve image quality, or the like.

### (2) Exposure

After disposing a mask to form a desired pattern on the obtained photosensitive resin layer, exposure may be performed by irradiating an actinic ray of i-line. As a light source used for irradiation, a low-pressure mercury lamp, a high-pressure mercury lamp, an ultra-high pressure mercury lamp, a metal halide lamp, an argon gas laser, or the like may be used. In an implementation, an X-ray, an electron beam, or the like may be used.

The exposure process may use, e.g., a light dose of 500 mJ/cm² or less (with a 365 nm sensor) when a high-pressure mercury lamp is used. In an implementation, the light dose may vary depending on kinds of each component, its combination ratio, and a dry film thickness. Through this step, fine adjustment of the pixel size is possible, enabling high-resolution implementation.

### (3) Development

In the development method, following the exposure step, an alkaline aqueous solution may be used as a developer to dissolve and remove unnecessary parts, leaving only the exposed parts remaining to form a pattern. Through this step, a profile may be formed to realize high resolution.

### (4) Post-Processing

There may be a post-heating process to obtain a pattern excellent in terms of heat resistance, light resistance, adhesion, crack resistance, chemical resistance, high strength, and storage stability of the image pattern obtained by development in the above process. In an implementation, after development, it may be heated in a convection oven at 250° C. for 1 hour. Through this step, color uniformity may be secured and clarity may be improved.

Some embodiments provide a display device including the black partition wall.

The display device may be a micro organic light emitting diode (OLED) display device.

Referring to the FIGURE, the micro organic light emitting diode (OLED) display device may include an OLED substrate deposited on a silicon wafer, an inorganic layer stacked on the OLED substrate, an adhesive protection layer stacked on the inorganic layer and a color filter layer that is stacked on the adhesive protection layer and converts white light generated from the OLED substrate into a plurality of color lights. In an implementation, the color filter layer may include a red color filter, a green color filter, and a blue color filter, and the black partition wall may be located between each color filter (e.g., may be between color filters of the color filter layer).

In some OLED substrates, OLEDs may be deposited on a glass or polyimide substrate. The micro OLED display device according to some embodiments may be more advantageous in implementing a micro display because the OLED may be deposited on a silicon wafer. These micro displays are in the spotlight as next-generation displays, and the micro displays are expected to be applied to devices such as MR.

In an implementation, the micro OLED display device may further include a micro lens array. The micro lens array may be on the adhesive protection layer and may surround the color filter layer and black partition wall.

The micro OLED display device with the above structure may be driven on a pixel basis by depositing WOLED on a highly integrated silicon wafer, and it may be easy to control the transmission wavelength through a color filter layer patterned with a resolution of less than or equal to about 3 μm, enabling high color reproduction and securing high resolution.

In an implementation, the adhesive protection layer may be a cured layer of a composition including a binder resin, a photopolymerization initiator, a photopolymerizable monomer, a solvent, and the like, and the lower inorganic layer may help prevent cracks from occurring by eliminating irregularities and increase the adhesion of the color filter layer.

In an implementation, the adhesive protection layer may have a thickness of less than or equal to about 1 μm. In this case, the above effect may be further maximized.

In an implementation, the color filter layer may have a thickness of about 1.1 μm to about 1.6 μm.

In an implementation, the black partition may have a thickness of about 0.5 μm to about 1.2 μm.

Maintaining the thickness of each of the color filter layer and the black partition as described above may help ensure that it is more advantageous to implement a micro OLED display device.

In an implementation, the inorganic layer may have a thickness of less than or equal to about 2 μm. Even with WOLED, light may not always diffuse in the direction perpendicular to the OLED substrate, so that color mixing of red, green, and blue could inevitably occur. An inorganic layer could be deposited on the OLED substrate to help prevent such color mixing. However, the color mixing may not be completely prevented even by depositing an inorganic layer and, in some embodiments, subtle light leakage phenomenon may be prevented by thinning the inorganic layer, e.g., controlling the thickness of the inorganic layer to less than or equal to about 2 μm. In an implementation, high resolution may be achieved by placing a black partition wall between the color filter layers.

In an implementation, the black photosensitive resin composition used as the material for the black partition wall may be a black material, and there could be issues with photocuring properties or the like. The photosensitive resin composition according to some embodiments allows the production of a cured layer only through low-temperature curing during prebaking and i-line photocuring, as described above, and there may be a huge difference in resolution that can be implemented compared to conventional display devices.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Example

### Preparation of Photosensitive Resin Composition

### Examples 1 to 6 and Comparative Examples 1 and 2

With the compositions shown in Table 1, the photopolymerization initiator was dissolved in a solvent and stirred at ambient temperature for 2 hours. The binder resin and the photopolymerizable monomer were added, and stirred at ambient temperature for 1 hour. After adding other additives and black colorant thereto, the solutions were stirred at ambient temperature for 1 hour, and then the entire solutions were stirred for 2 hours. The solutions were filtered three times to remove impurities to prepare each photosensitive resin composition.

TABLE 1
(unit: g)

| | | | | | | | | Comp. | Comp. |
|---|---|---|---|---|---|---|---|---|---|
| | | Ex. 1 | Ex. 2 | Ex. 3 | Ex. 4 | Ex. 5 | Ex. 6 | Ex. 1 | Ex. 2 |
| (A) Binder resin | | 7.89 | 7.89 | 7.89 | 7.89 | 7.89 | 7.89 | 7.89 | 7.89 |
| (B) Black | (B-1) | 67.68 | 57.53 | 33.84 | 58.51 | 75.08 | 81.06 | — | — |
| colorant | (B-2) | — | 10.15 | — | — | — | — | 67.68 | — |
| | (B-3) | — | — | 11.11 | — | — | — | — | 22.21 |
| | (B-4) | — | — | 11.21 | — | — | — | — | 22.42 |
| | (B-5) | — | — | 11.55 | — | — | — | — | 23.10 |
| (C) | | 3.04 | 3.04 | 3.04 | 3.04 | 3.04 | 3.04 | 3.04 | 3.04 |
| Photopolymerizable | | | | | | | | | |
| monomer | | | | | | | | | |
| (D) | | 0.79 | 0.79 | 0.79 | 0.79 | 0.79 | 0.79 | 0.79 | 0.79 |
| Photopolymerization | | | | | | | | | |
| initiator | | | | | | | | | |
| (E) Solvent | | 20.25 | 20.25 | 20.25 | 29.42 | 12.85 | 6.87 | 20.25 | 20.25 |
| (F) Other | (F-1) | 0.02 | 0.02 | 0.02 | 0.02 | 0.02 | 0.02 | 0.02 | 0.02 |
| additives | (F-2) | 0.23 | 0.23 | 0.23 | 0.23 | 0.23 | 0.23 | 0.23 | 0.23 |
| | (F-3) | 0.06 | 0.06 | 0.06 | 0.06 | 0.06 | 0.06 | 0.06 | 0.06 |

### (A) Binder Resin

Acrylic binder resin (SP-RY92-M10; Resonac Corporation) (a double bond equivalent weight of greater than or equal to about 340 g/mol)

### (B) Black Colorant

(B-1) Lactam black mill base (BC4001, SAKATA; solid content 15 wt %)
(B-2) Carbon black mill base (CI-M463, SAKATA; solid content 15 wt %)
(B-3) Red pigment mill base (BA6228, SAKATA; solid content 15 wt %)
(B-4) Green pigment mill base (BJ1564, SAKATA; solid content 15 wt %)
(B-5) Blue pigment mill base (BB6136, SAKATA; solid content 15 wt %)

### (C) Photopolymerizable Monomer

Dipentaerythritol hexa(meth)acrylate (DPHA, Nippon Kayaku Co. Ltd.)

### (D) Photopolymerization Initiator

Oxime initiator (SPI-03W, Samyang Corporation)

### (E) Solvent

Propylene glycol monomethyl ether acetate (PGMEA, Sigma-Aldrich Corporation)

### (F) Other Additives

(F-1) Leveling agent (F-556, DIC Co., Ltd.)
(F-2) Surfactant (KBM-503, Shin-Etsu Chemical Co., Ltd.)
(F-3) Polymerization inhibitor (MHQ, JHChem)

### Evaluation 1

Each of the photosensitive resin compositions according to Examples 1 to 6 and Comparative Examples 1 and 2 was coated on a 10 cm*10 cm ITO glass (resistance: 3002) and heated on a hot plate at 100° C. in a proxy type for 1 minute and then, in contact type for 1 minute again to form a 1 μm-thick photosensitive resin layer. The resin film was measured with respect to optical density (OD) by using a densitometer 361T made by X-Rite Inc., and the results are shown in Table 2.

TABLE 2

| | | | | | | | Comp. | Comp. |
|---|---|---|---|---|---|---|---|---|
| | Ex. 1 | Ex. 2 | Ex. 3 | Ex. 4 | Ex. 5 | Ex. 6 | Ex. 1 | Ex. 2 |
| Optical | 2.95 | 1.63 | 1.54 | 1.85 | 2.53 | 1.81 | 1.31 | 1.06 |
| density (/μm) | | | | | | | | |

### Evaluation 2

The substrate coated with the photosensitive resin layer was exposed to light by using a mask engraved with patterns of various sizes and changing an exposure dose with a light exposer (UX-1200SM-AKS02 made by Ushio Inc.), developed at ambient temperature in a 2.38% TMAH solution (aqueous developer) to dissolve and remove an exposed region, and washed with pure water for 50 seconds, obtaining a cured layer.

The cured layer was examined with respect to a minimum size of the patterns by using a micro optical microscope (STM6-LM, Olympus Corp.) to measure resolution of the patterns. At an optimal exposure dose that 2 μm line patterns had a line width (critical dimension (CD), unit: μm) of less than 3 μm, a minimum pattern dimension after the curing was measured. A line width of less than or equal to 1.5 μm was given ⊚, a line width of less than or equal to 2 μm was given o, greater than 2 μm and less than 3 μm was given Δ, and greater than or equal to 3 μm was given X, and the results are shown in Table 3.

TABLE 3

| | | | | | | | Comp. | Comp. |
|---|---|---|---|---|---|---|---|---|
| | Ex. 1 | Ex. 2 | Ex. 3 | Ex. 4 | Ex. 5 | Ex. 6 | Ex. 1 | Ex. 2 |
| Resolution | ⊚ | Δ | Δ | Δ | ◯ | Δ | X | X |

Referring to Tables 2 and 3, the black photosensitive resin compositions according to the Examples, which was a composition having high optical density and curable at a low temperature of 100° C. or lower to implement ultra-high resolution patterns of less than 3 μm, was applicable to micro OLED display devices.

By way of summation and review, in the micro OLED display panels, which may have about 10 times smaller pixels than general OLED display panels, it may be difficult to precisely form red (R)/green (G)/blue (B) light emitting layers by using FMM (Fine Metal Mask) technology, so color filters may be applied thereto.

The color filters applied to the micro OLED display panels may be made of light-sensitive organic material materials, in which particles that exist in a dispersed form have a wide bandwidth transmittance spectrum for each RGB, and may have low color reproducibility (color gamut) and fine light leakage occurrence.

As an alternative to improving the low color gamut, color filters made of inorganic materials may be considered but they may have a narrow bandwidth transmittance spectrum for each RGB and thus may have high color gamut but may still exhibit excessive light leakage occurrence. Accordingly, technologies capable of completely blocking the light leakage, while providing the high color reproducibility, may be considered.

Photosensitive resin compositions may be used for manufacturing the color filters, liquid crystal display materials, display devices such as organic light emitting diodes and the like, display elements such as display device panel materials and the like. For example, the color filters such as color liquid crystal displays and the like may use a photosensitive resin layer such as a black partition wall at a boundary between colored layers such as red, green, blue, and the like in order to enhance display contrast or color development effect, and this photosensitive resin layer may be formed of a black photosensitive resin composition.

Some black photosensitive resin compositions may be used to form a cured layer such as the black partition wall and the like, and the curing (baking) process may be performed at a high temperature of greater than about 150° C. Accordingly, the cured layer may be directly formed on the display devices, and this may result in deteriorating internal elements of the display devices.

Therefore, black photosensitive resin compositions for micro OLED may be cured at a low temperature, completely block the light leakage phenomenon, etc., and may implement ultra-high resolution patterns.

One or more embodiments may provide a black photosensitive resin composition that has high optical density, can be cured at low temperatures, and can implement ultra-high resolution patterns of 2 μm or less.

A micro OLED display device including the black partition wall formed by curing the lactam black-containing black photosensitive resin composition according to an embodiment at a low temperature may exhibit excellent light leakage-blocking ability and may implement ultra-high resolution patterns and thus may be applied to VR (Virtual Reality), AR (Augmented Reality), and MR (Mixed Reality) devices, which have recently begun to be released on the market. Some embodiments may provide a black photosensitive resin composition for forming a black partition wall curable at a low temperature and having excellent chemical resistance, e.g., a black photosensitive resin composition having high reliability and patternability by a prebaking temperature at about 100° C. or lower and photocuring (i-line exposure) alone, which differs from another material a black material in that the black photosensitive resin composition has characteristics of being cured at a low temperature of about 100° C. or lower, implements ultra-high resolution patterns of about 2 μm or less, and may have optical density (/μm) of about 1.5 or more, e.g., about 2.0 or more.

Example embodiments have been disclosed herein, and although specific terms are employed, they are used and are to be interpreted in a generic and descriptive sense only and not for purposes of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A black photosensitive resin composition, comprising:
a binder resin;
a black colorant including lactam black;
a photopolymerizable monomer;
a photopolymerization initiator; and
a solvent,
wherein the black photosensitive resin composition has an optical density (OD) per 1 μm of greater than or equal to about 1.5.

2. The black photosensitive resin composition as claimed in claim 1, wherein the black colorant is included in an amount of about 60 wt % to about 80 wt %, based on a total weight of the black photosensitive resin composition.

3. The black photosensitive resin composition as claimed in claim 1, wherein the black colorant includes a lactam black mill base.

4. The black photosensitive resin composition as claimed in claim 3, wherein the black photosensitive resin composition has an OD per 1 μm of greater than or equal to about 2.0.

5. The black photosensitive resin composition as claimed in claim 1, wherein the black photosensitive resin composition is curable at a temperature of less than or equal to about 100° C.

6. The black photosensitive resin composition as claimed in claim 1, wherein the binder resin includes an acrylic binder resin.

7. The black photosensitive resin composition as claimed in claim 6, wherein the acrylic binder resin has a double bond equivalent weight of greater than or equal to about 340 g/mol.

8. The black photosensitive resin composition as claimed in claim 1, wherein the black photosensitive resin composition includes, based on a total weight of the black photosensitive resin composition:
about 1 wt % to about 10 wt % of the binder resin;
about 60 wt % to about 80 wt % of the black colorant;
about 0.5 wt % to about 5 wt % of the photopolymerizable monomer;
about 0.1 wt % to about 3 wt % of the photopolymerization initiator; and
the solvent.

9. The black photosensitive resin composition as claimed in claim 1, further comprising malonic acid, 3-amino-1,2-propanediol, a silane coupling agent, a leveling agent, a surfactant, a polymerization inhibitor, or a combination thereof.

10. A black partition wall manufactured using the black photosensitive resin composition as claimed in claim 1.

11. A display device comprising the black partition wall as claimed in claim 10.

12. The display device as claimed in claim 11, wherein:
the display device is a micro OLED display device including an OLED substrate deposited on a silicon wafer, an inorganic layer stacked on the OLED substrate, an adhesive protection layer stacked on the inorganic layer and a color filter layer that is stacked on the adhesive protection layer and converts white light generated from the OLED substrate into a plurality of color lights,
the color filter layer includes a red color filter, a green color filter, and a blue color filter, and
the black partition wall is between each color filter of the color filter layer.

13. The display device as claimed in claim 12, further comprising a micro lens array on the adhesive protection layer and surrounding the color filter layer and the black partition wall.

14. The display device as claimed in claim 12, wherein the adhesive protection layer has a thickness of less than or equal to about 1 μm.

15. The display device as claimed in claim 12, wherein the color filter layer has a thickness of about 1.1 μm to about 1.6 μm.

16. The display device as claimed in claim 12, wherein the black partition wall has a thickness of about 0.5 μm to about 1.2 μm.

17. The display device as claimed in claim 12, wherein the inorganic layer has a thickness of less than or equal to about 2 μm.

18. A method of manufacturing a black partition wall, comprising:
coating the black photosensitive resin composition as claimed in claim 1;
prebaking at a temperature of less than or equal to about 100° C. after the coating;
exposing to i-line after the prebaking, and
developing after the exposing.
